(19) United States
(12) Patent Application Publication
(10) Pub. No.: US 2026/0248010 A1
(43) Pub. Date: Aug. 20, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Yi-Chun Huang, Miaoli County (TW); Yen-Ping Wang, Changhua County (TW)

(73) Assignee: Taiwan Semiconductor Manufacturing Company, Ltd., Hsinchu (TW)

(21) Appl. No.: 19/056,783

(22) Filed: Feb. 19, 2025

(51) Int. Cl. H01L 23/00; H01L 23/14; H01L 23/31; H01L 23/48; H01L 25/07

(52) U.S. Cl. CPC H10W 70/698; H10W 74/141; H10W 90/00; H10W 20/20; H10W 72/01255; H10W 72/019; H10W 72/01935; H10W 72/244; H10W 72/29; H10W 72/923; H10W 72/934; H10W 72/952; H10W 90/297; H10W 90/792; H10W 90/794

(57) ABSTRACT

A semiconductor package includes a first die, a plurality of conductive bumps and a second die. The first die includes a first substrate, a plurality of first through vias extending through the first substrate, a plurality of copper pads over a backside of the first substrate, wherein each of the plurality of copper pads is aluminum free, and a plurality of first connectors over a front side of the first substrate. The plurality of conductive bumps are disposed on the plurality of copper pads respectively. The second die is bonded over the first die and includes a second substrate, and a plurality of second connectors over a front side of the second substrate and directly bonded to the plurality of first connectors respectively.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 illustrate cross sectional views of intermediate stages in the manufacturing of a semiconductor package according to some embodiments of the present disclosure.

FIG. 10 to FIG. 18 illustrate partial-enlarged cross sectional views of intermediate stages in the manufacturing of a semiconductor package according to some embodiments of the present disclosure.

FIG. 19 illustrates a partial-enlarged cross sectional view of a semiconductor package according to some embodiments of the present disclosure.

FIG. 20 illustrates a cross sectional view of a semiconductor package according to some embodiments of the present disclosure.

FIG. 21 illustrates a cross sectional view of a semiconductor package according to some embodiments of the present disclosure.

FIG. 22 illustrates a cross sectional view of a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of the embodiments described herein. Some embodiments described herein are described in the context of 3D IC packages or 2.5D IC packages. Some variations of the exemplary methods and structures are described in the embodiments of the disclosure. A person having ordinary skill in the art will readily understand other modifications may be made that are contemplated within the scope of other embodiments. Although embodiments of the method may be described in a particular order, various other embodiments of the method may be performed in any logical order and may include fewer or more steps than what is described herein. The upper die in the semiconductor package in the disclosure is bonded in a face-to-face (F2F) stacking. However, other bonding of the semiconductor package such as face-to-back (F2B) stacking may also be adopted. The bonding pitches of the semiconductor package may be in a monotonically increasing order from the topmost tier to the bottommost tier, where the topmost bonding tier has the finest bond pitch and the bottommost bonding tier has the coarsest bond pitch.

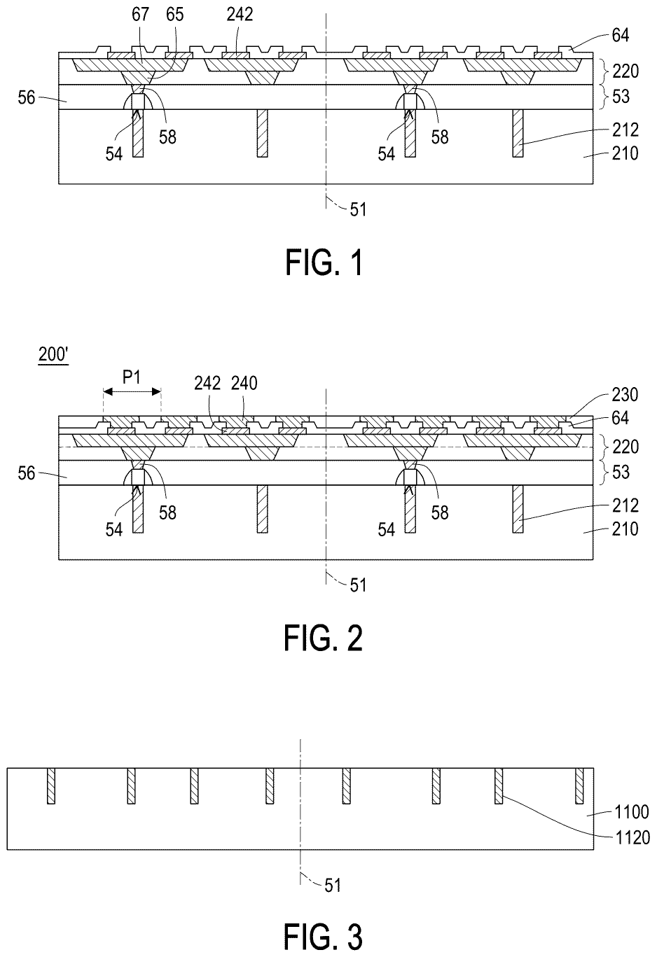

FIG. 1 to FIG. 9 illustrate cross sectional views of intermediate stages in the manufacturing of a semiconductor package according to some embodiments of the present disclosure. The process for forming the semiconductor package is illustrated with three tiers of integrated circuit wafers at the wafer-to-wafer (W2W) scale, in accordance with some embodiments.

FIG. 1 through FIG. 2 illustrate various intermediate steps in manufacturing an integrated circuit wafer 200′, also referred to as an upper wafer 200′, in accordance with some embodiments. Referring first to FIG. 1, the upper wafer 200′ may be a logic wafer (e.g., central processing unit (CPU), graphics processing unit (GPU), system-on-a-chip (SoC), application processor (AP), microcontroller, ASIC, FPGA, etc.), a memory wafer (e.g., dynamic random access memory (DRAM) wafer, static random access memory (SRAM) wafer, Non-Volatile Memory (NVM) wafer, etc.), a radio frequency (RF) wafer, a sensor wafer, a micro-electro-mechanical-system (MEMS) wafer, a signal processing wafer (e.g., digital signal processing (DSP) wafer), a front-end wafer (e.g., analog front-end (AFE) wafers), the like, or combinations thereof.

The upper wafer 200′ may include different device regions that are singulated in subsequent steps to form a plurality of integrated circuit packages, such as along the scribe line 51. The upper wafer 200′ may be processed according to applicable manufacturing processes to form integrated circuits. For example, in some embodiments the upper wafer 200′ includes a semiconductor substrate 210, such as silicon, doped or undoped, or an active layer of a semiconductor-on-insulator (SOI) substrate. The semiconductor substrate 210 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 210 has an active surface (e.g., the surface facing upwards in FIG. 1), hereinafter referring to as a front side, and an inactive surface (e.g., the surface facing downwards in FIG. 1), hereinafter referring to as a back side.

Referring to FIG. 2, in some embodiments, the upper wafer 200′ includes a plurality of upper dies. In one embodiments, each of the upper dies may include at least one through semiconductor via 212 formed in a semiconductor substrate 210 for electrical connection. In some embodiments, an interconnect structure 220 formed over the semiconductor substrate 210 and electrically connected to the through semiconductor vias 212, a bonding layer 230 formed over the interconnect structure 220, and a plurality of connectors 240 embedded in the bonding layer 230 and electrically connected to the interconnect structure 220. It should be noted that the existence and the number of through semiconductor vias 212 merely serves as an illustrative example, and the disclosure is not limited thereto. In other embodiments, the upper die may include more or less semiconductor vias 212, or may not include any semiconductor vias 212.

Referring back to FIG. 1, in some embodiments, a device layer 53 including devices (represented by a transistor, but not limited thereto) 54 and an inter-layer dielectric (ILD) 56 may be formed at the front surface of the semiconductor substrate 52. The devices 54 may be active devices (e.g., transistors, diodes, etc.), capacitors, resistors, etc. The ILD 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

In some embodiments, a plurality of conductive plugs 58 extend through the ILD 56 to electrically and physically couple the devices 54. For example, when the devices 54 are transistors, the conductive plugs 58 may couple the gates and source/drain regions of the transistors. The conductive plugs 58 may be formed of tungsten, cobalt, nickel, copper, silver, gold, aluminum, the like, or combinations thereof.

In accordance with some embodiments of the disclosure, a semi-global interconnect 220, also referred to as an interconnect structure 220, is formed over the ILD 56 and the conductive plugs 58. The interconnect structure 220 interconnects the devices 54 to form an integrated circuit. The interconnect structure 220 includes conductive vias and lines embedded in an inter-metal dielectric (IMD) layer. In addition to providing insulation between various conductive elements, an IMD layer may include one or more dielectric etch stop layers to control the etching processes that form openings in the IMD layer. Generally, vias conduct current vertically and are used to electrically connect two conductive features located at vertically adjacent levels, whereas lines conduct current laterally and are used to distribute electrical signals and power within one level. The interconnect structure 220 is in the back end of line (BEOL) scheme.

The interconnect structure 220 may be formed using, for example, a dual damascene process flow. First, a dielectric stack used to form IMD layer 63 may be deposited using silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first IMD layer 63 may be deposited using any suitable method, such as CVD, physical vapor deposition (PVD), ALD, PEALD, PECVD, SACVD, FCVD, spin-on, and/or the like, or a combination thereof. In some embodiments, IMD layer 63 includes an etch stop layer (not shown) positioned at the bottom of the dielectric stack. The etch stop layer includes one or more insulator layers (e.g., SiN, SiC, SiCN, SiCO, CN, combinations thereof, or the like) having an etch rate different than an etch rate of an overlying material. In some embodiments, the materials used to deposit the dielectric stack for the IMD layer 63 may be different from those used in forming the ILD 56 in order to provide an etch selectivity between the IMD layer 63 and the ILD 56.

Appropriate photolithography and etching techniques (e.g., anisotropic RIE employing fluorocarbon chemistry) may be used to pattern the IMD layer 63 to form openings for vias and lines. The openings for vias may be vertical holes extending through IMD layer 63 to expose a top conductive surface of conductive plugs 58, and openings for lines may be longitudinal trenches formed in an upper portion of the IMD layer 63. In some embodiments, the method used to pattern holes and trenches in the IMD layer 63 utilizes a via-first scheme, wherein a first photolithography and etch process form holes for vias, and a second photolithography and etch process form trenches for lines and extends the holes for vias. Other embodiments may use a different method, for example, a trench-first scheme, or an incomplete via-first scheme, or a buried etch stop layer scheme. The etching techniques may utilize multiple steps. For example, a first main etch step may remove a portion of the dielectric material of IMD layer 63 and stop on an etch stop dielectric layer. Then, the etchants may be switched to remove the etch stop layer dielectric materials. The parameters of the various etch steps (e.g., chemical composition, flow rate, and pressure of the gases, reactor power, etc.) may be tuned to produce tapered sidewall profiles with a desired interior taper angle.

One or more conductive materials may be deposited to fill the holes and trenches forming the conductive features 65 and 67. The openings may be first lined with a conductive diffusion barrier material to form a conductive diffusion barrier liner (not shown) and then completely filled with a conductive fill material deposited over the conductive diffusion barrier liner. In some embodiments, a thin conductive seed layer (not shown) may be deposited over the conductive diffusion barrier liner to help initiate an electrochemical plating (ECP) deposition step that completely fills the openings with a conductive fill material.

The conductive diffusion barrier liner in the vias 65A and lines 67A includes one or more layers of TaN, Ta, TiN, Ti, Co, or the like, or combinations thereof. The conductive fill layer in the vias 65 and lines 67 may include metals such as Cu, Al, W, Co, Ru, or the like, or combinations thereof, or multi-layers thereof. The conductive materials used in forming the conductive features 65 and 67 may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like). In some embodiments, the sidewalls of the vias 65 and lines 67 are tapered inwards moving down in the direction towards a top surface of the ILD 56.

Any excess conductive material over the IMD layer 63 outside of the openings may be removed by a planarizing process (e.g., CMP) thereby forming a top surface comprising dielectric regions of IMD layer 63A that are substantially coplanar (within process variations) with conductive regions of conductive lines 67. The planarization step embeds the conductive vias 65 and conductive lines 67 into IMD layer 63. The above process for forming the interconnect structure 200 is but one example, and other embodiments may use different processes, materials, and/or structures. For example, additional liner structures may be utilized, different etch processes, and the like may be utilized. It is noted that the interconnect structure 200 herein is illustrated as a single layer for illustrative purposes, and in some embodiments, the interconnect structure 200 may include a plurality of layers.

Referring further to FIG. 1, a plurality of upper front side conductive pads 242 are formed over the front side of the semiconductor substrate 210. The upper front side conductive pads 242 may include aluminum (Al), aluminum alloy, or the like. In some embodiments, the upper front side conductive pads 242 may include a conductive material such as, e.g., copper, titanium, tungsten, aluminum, or the like, to which external connections are made. The upper front side conductive pads 242 are on the active side of the semiconductor substrate 210, such as in and/or on the interconnect structure 200 making electrical contact with conductive features of the interconnect structure 200. One or more passivation films 64 may extend over portions of the interconnect structure 200 and the conductive pads 242. Openings extend through the passivation films 64 to the conductive pads 242.

Optionally, solder regions (e.g., solder balls or solder bumps) may be disposed on the conductive pads 242. A chip probe (CP) testing may be performed on the upper wafer 200′ to ascertain whether the upper wafer 200′ is a known good wafer (and/or whether the individual unsingulated die is a known good die). After testing, the solder regions may be removed.

With now reference to FIG. 2, a bonding layer 230 is formed over the upper wafer 200′ and a plurality of lower connectors 240, also referred to as bonding pads 240, are formed on the conductive pads 242 for providing electrical connection of the devices 54 to subsequently attached wafers (see below, FIG. 5). The bonding layer 230 may be a dielectric material such as SiCN and/or an oxide, e.g. silicon oxide, or the like. The bonding layer 230 may be formed, for example, by spin coating, lamination, chemical vapor deposition (CVD), or the like. However, any suitable method or materials may be used.

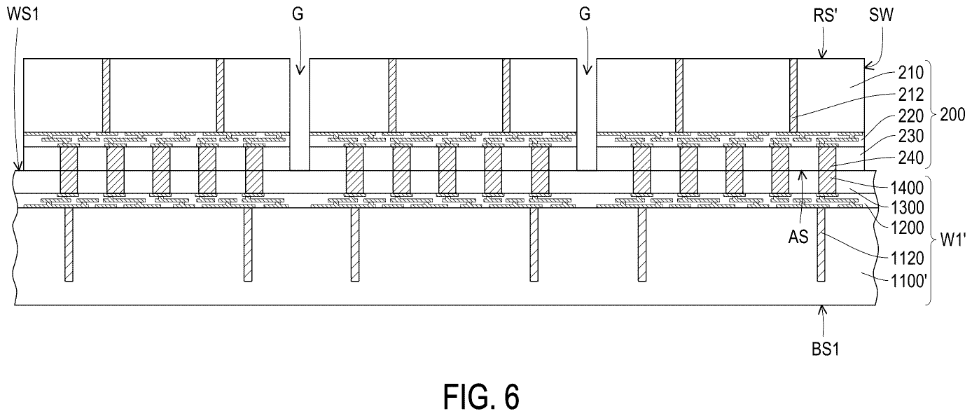

FIG. 2 further shows that the lower connectors 240 are formed on upper surfaces of the conductive pads 62. The lower connectors 240 may exhibit fine pitches P1 in a range of about 100 nm to about 10000 nm. In some embodiments, the lower connectors 240 are formed with a damascene process in which the bonding layer 230 is patterned and etched utilizing photolithography techniques to form trenches corresponding to the desired pattern of conductive pads. In some embodiments, the lower connectors 240 are formed with a dual damascene process with vias disposed between the conductive pads 242 and the lower connectors 240. An optional diffusion barrier and/or optional adhesion layer may be deposited and the trenches may be filled with a conductive material. Suitable materials for the diffusion barrier layer includes titanium, titanium nitride, titanium oxide, tantalum, tantalum nitride, titanium oxide, or other alternatives, and suitable materials for the conductive material include copper, silver, gold, tungsten, aluminum, combinations thereof, or the like. In an embodiment, the conductive pads 66 may be formed by depositing a seed layer of copper or a copper alloy, and filling the trenches by electroplating. A chemical mechanical planarization (CMP) process or the like may be used to remove excess conductive material from a surface of the bonding layer 68 and to planarize the surface for subsequent processing. Then, the upper wafer 200′ may be singulated along the scribe line 51 to form a plurality of upper dies (e.g., the upper dies 200 illustrated in FIG. 6).

FIG. 3 to FIG. 5 illustrate various intermediate steps in manufacturing a lower wafer W1′ such as a power rail wafer, which will subsequently be bonded to the upper dies 200, in accordance with some embodiments. Referring first to FIG. 3, the lower wafer W1′ includes a plurality of lower through vias 1120, also referred to as through substrate vias (TSVs), extending into a lower substrate 1100, such as a semiconductor substrate, of the lower wafer W1′. In an embodiment of the lower wafer W1′ being a power rail wafer, the lower through vias 1120 are electrically coupled to a subsequently formed power distribution network (PDN) on the back side of the semiconductor substrate 1100, e.g., the side of the semiconductor substrate 1100 facing downward in FIG. 3. As an example to form the lower through vias 1120, recesses can be formed in the lower substrate 1100 by, for example, etching, milling, laser techniques, a combination thereof, and/or the like. A thin dielectric material may be formed in the recesses, such as by using an oxidation technique. A barrier layer (not illustrated) may be conformally deposited in the openings, such as by CVD, atomic layer deposition (ALD), physical vapor deposition (PVD), thermal oxidation, a combination thereof, and/or the like. The barrier layer may be formed from an oxide, a nitride, or an oxynitride, such as titanium nitride, titanium oxynitride, tantalum nitride, tantalum oxynitride, tungsten nitride, a combination thereof, and/or the like. A conductive material may be deposited over the barrier layer and in the openings. The conductive material may be formed by an electro-chemical plating process, CVD, PVD, a combination thereof, and/or the like. Examples of conductive materials are copper, tungsten, aluminum, silver, gold, a combination thereof, and/or the like. Excess of the conductive material and the barrier layer is removed from the surface of the lower substrate 1100 by, for example, a chemical mechanical polish (CMP). Remaining portions of the barrier layer and the conductive material form the lower through vias 1120.

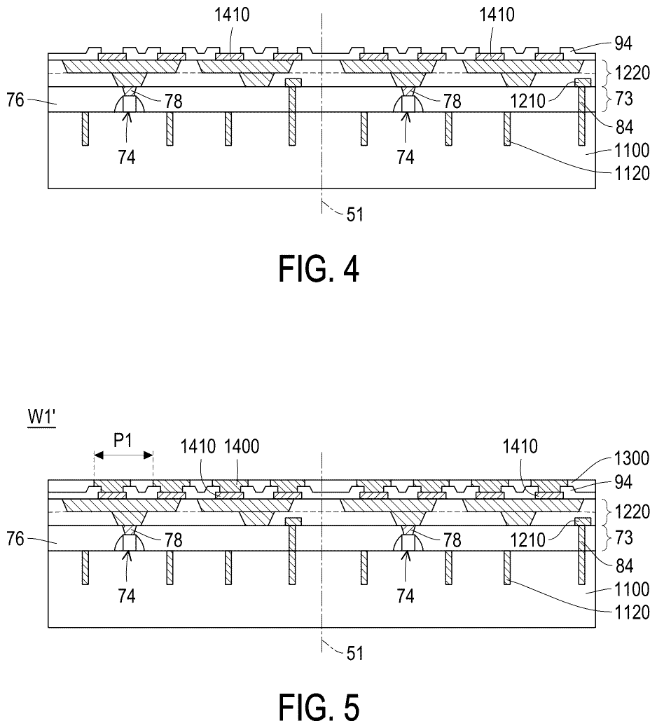

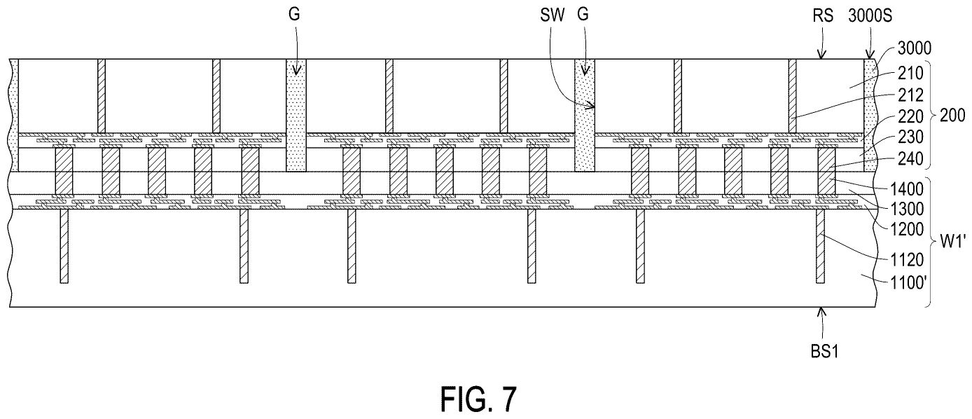

In the embodiment illustrated, the lower through vias 1120 are not yet exposed at the back side of the lower substrate 1100 (see below, FIG. 4). Rather, the lower through vias 1120 are buried in the lower substrate 1100. As will be discussed in greater detail below (see FIG. 7), the lower through vias 1120 will be exposed at the back side of the lower substrate 1100 after being bonded to the upper dies 200 in subsequent processing. In some embodiments, the lower through vias 1120 may have diameters in a range of about 50 nm to about 200 nm. The lower through vias 1120 may be electrically coupled to conductive lines or other conductive features (not illustrated) of the lower substrate 1100 or device layer 73.

FIG. 4 illustrates the lower wafer W1′ after forming a device layer 73, a semi-global interconnect (also referred to as an interconnect structure 1200), a plurality of lower front side conductive pads 1410, and one or more passivation films 94 over the semiconductor substrate 1100. In some embodiments, the device layer 73, the interconnect structure 1200, the lower front side conductive pads 1410, and one or more passivation films 94 are formed using similar methods and materials as the corresponding layers of the upper wafer 200′ described above with respect to FIG. 1 and FIG. 2. The device layer 73 includes conductive features electrically coupled to the lower through vias 1120, and an ILD 76 is formed over the devices 74 and the lower substrate 1100. In some embodiments, the device layer 73 includes devices 74 (e.g. active devices such as transistors). In other embodiments, the device layer 73 is omitted and the ILD 76 is formed over the lower substrate 1100 without covering active devices. The lower wafer W1′ not containing active devices may be useful for improving power efficiency and thermal management for devices in the upper wafer 200′. Conductive plugs 78 extend through the ILD 76 to electrically couple to the devices 74. The interconnect structure 1200 is formed over the ILD 76. The interconnect structure 1200 may be formed using the same methods and materials as the interconnect structure 220 such as e.g. damascene or dual damascene processes, as described above with respect to FIG. 2. The lower front side conductive pads 1410 are physically and electrically coupled to the interconnect structure 1200, and one or more passivation films 94 are over the active side of the upper wafer 200′ with openings extending to the conductive pads 1410.

The lower through vias 1120 may be directly connected to the devices 74, connected to the devices 74 through the interconnect structure 1200, or a combination thereof. In an embodiment of the lower wafer W1′ being a power rail wafer, the PDN will be subsequently formed along the backside of the lower substrate 1100, and the lower through vias 1120 may be connected to voltages at VSS and VDD via the subsequently-formed PDN. Power may also be routed through the interconnect structure 1200 vertically by short paths through dedicated conductive vias and lines.

In some embodiments, a plurality of contacts 84 may be formed through the ILD 76 to electrically couple the lower through vias 1120 to a plurality of conductive features 1210 (e.g. metal lines or vias of a first metallization pattern) of the interconnect structure 1200. The contacts 84 may be formed through the ILD 76 using substantially similar methods and materials as the conductive plugs 78 formed in the ILD 76. However, any suitable process and materials may be used.

The contacts 84 and the lower through vias 1120 are illustrated as two separate elements for illustrative purposes, and in some embodiments, the contacts 84 and lower through vias 1120 may be a single continuous element. For example, in some embodiments the lower through vias 1120 may be formed after forming one or more dielectric layers over the substrate, such as the ILD 76 and/or one or more layers of the interconnect structure 1200. After forming the one or more dielectric layers, an opening may be formed through the one or more dielectric layers and into the lower substrate 1100 and filled with conductive material. The dimensions of the lower through vias 1120 connecting to the contacts 84 may be larger than the dimensions of the lower through vias 1120 directly connecting to device 74, which may be useful for higher power delivery and lower power consumption.

FIG. 5 illustrates a bonding layer 1300 formed over the lower wafer W1′ and a plurality of lower connectors 1400 formed over the front side of the lower substrate 1100. In some embodiments, the lower connectors 1400 are formed on top surfaces of the lower front side conductive pads 1410. The lower connectors 1400 and the bonding layer 1300 may be used to bond the active side of the lower wafer W1′ to the active side of the upper dies/wafer 200 (see below, FIG. 6). The bonding layer 1300 and the lower connectors 1400 may be formed using substantially similar methods and materials as the bonding layer 230 and the upper connectors 240 as described above in reference to FIG. 2. However, any suitable method or materials may be used. The lower connectors 1400 may exhibit fine pitches the same as pitch P1 (see above, FIG. 2) in a range of about 100 nm to about 10000 nm. The lower front side conductive pads 1410 may include aluminum (Al), aluminum alloy, or the like. In some embodiments, the lower front side conductive pads 1410 may include a conductive material such as, e.g., copper, titanium, tungsten, aluminum, or the like, to which external connections are made. The lower front side conductive pads 1410 are on the active side of the lower substrate 1100, such as in and/or on the interconnect structure 1200, for making electrical contact with conductive features of the interconnect structure 1200.

With now reference to FIG. 6, in some embodiments, a plurality of upper (second) dies 200, which are formed by dicing the upper wafer 200′ shown in FIG. 2 along the scribe lines 51, are bonded with the lower (first) wafer W1′. In the present embodiment, the bonding is performed at the die-to-wafer level. Alternatively, the bonding may be performed at the die-to-die level or wafer-to-wafer level. The disclosure is not limited thereto. The upper dies 200 are bonded to the lower wafer W1′ by directly bonding the upper connectors 240 to the lower connectors 1400.

In some embodiments, the lower connectors 1400 may include aluminum pads or other suitable metal pads, which are embedded in the bonding layer 1300. The lower connectors 1400 are electrically coupled to the lower substrate 1100 through the interconnect structure 1200. The bonding layer 1300 may provide a degree of protection for the underlying structures. For example, the bonding layer 1300 can be formed of silicon oxide, silicon nitride, silicon oxy-nitride, low-k dielectrics, combinations thereof, or the like. In some embodiments, at least a portion of the lower connectors 1400 are revealed by the bonding layer 1300. The top surfaces of the lower connectors 1400 and the top surface of the bonding layer 1300 may be substantially level. In some embodiments, the top surfaces of the lower connectors 1400 and the top surface of the bonding layer 1300 are collectively referred to as a wafer bonding surface WS1.

In some embodiments, the upper connectors 240 may include aluminum pads or other suitable metal pads, and the bonding layer 230 may be a dielectric layer such as a silicon oxide layer, a silicon nitride layer, a silicon oxy-nitride layer, or a dielectric layer formed by other suitable dielectric materials. In some embodiments, the upper connectors 240 of the upper dies 200 including bonding pads are partially revealed by the openings of the bonding layer 230. In some embodiments, top surfaces of the upper connectors 240 and a top surface of the bonding layer 230 are collectively referred to as an active surface AS of each of the upper dies 200. For example, each of the upper dies 200 may include the active surface AS, a rear surface RS′ opposite to the active surface AS, and the sidewalls SW connected to the active surface AS and the rear surface RS′. In some embodiments, the through semiconductor vias 212 are not revealed by the rear surface RS′ at this stage. In some embodiments, the top surfaces of the upper conductors 240 and the top surface of the bonding layer 230 may be substantially located at the same level height to provide an appropriate active surface AS for a subsequent bonding process.

In some embodiments, the upper dies 200 are picked-and-placed onto the wafer bonding surface WS1 of the lower wafer W1′. In some embodiments, a gap G is formed between two adjacent upper dies 200. In some alternative embodiments, some of the various upper dies 200 may be directly adjacent one another such that no gap is formed between the upper dies 200. In other words, the upper dies 200 may be spaced apart or immediately disposed side by side. In some embodiments, the upper dies 200 and the lower wafer W1′ are bonded in a face-to-face alignment. For example, the active surface AS of each of the upper dies 200 and the wafer bonding surface WS1 of the lower wafer W1 may face each other and may be in physical contact with each other. In some embodiments, the lower connectors 1400 of the lower wafer W1′ are substantially aligned and in contact with the upper conductors 240 of the upper dies 200. For example, the center of the lower connectors 1400 may be substantially positioned to the center of the upper conductors 240. The upper dies 200 and the lower wafer W1′ are bonded using metal to metal bonding, dielectric to dielectric bonding, fusion bonding, direct bonding, dielectric bonding, metal bonding, solder joints, or other applicable techniques, such that the upper dies 200 are electrically connected to the lower wafer W1′.

For example, the bonding layers 230 of the upper dies 200 are bonded to the bonding layer 1300 of the lower wafer W1′ using direct dielectric-to-dielectric bonding, and the upper connectors 240 of each of the upper dies 200 are bonded to the lower connectors 1400 of the lower wafer W1′ using direct metal-to-metal bonding. In such embodiments, covalent bonds are formed with oxide layers, such as the dielectric layers 230 of the upper dies 200. In some embodiments, before performing the bonding process, a surface treatment may be performed on the upper dies 200. Next, a pre-bonding process may be performed to align the upper dies 200 with the lower wafer W1′. For example, the alignment of the upper dies 200 and the lower wafer W1′ may be achieved using optical sensing, alignment marks, or other applicable techniques. Subsequently, the upper dies 200 and the lower wafer W1′ may be pressed against together to form weak bonds at the interface therebetween. For example, a pressing force may be applied to press the upper dies 200 and the lower wafer W1′ against one another. In some embodiments, the pre-bonding step may be performed at the room temperature. In alternative embodiments, higher temperatures may be used during the pre-bonding step.

After the pre-bonding process, the upper dies 200 and the lower wafer W1′ are treated to strengthen the weak bonds using, for example, an annealing process, other heating techniques, or the like. For example, during the annealing process, OH bonds in the bonding layers 230 of the upper dies 200 and the bonding layer 1300 of the lower wafer W1′ may break to form the strong bonds between the upper dies 200 and the lower wafer W1', and hence the upper dies 200 and the lower wafer W1′ are bonded to one another through, for example, fusion bonds or Van Der Waals force. In some embodiments, during the metal to metal bonding, the metal (e.g., copper) in the upper connectors 240 of the upper dies 200 and the lower connectors 1400 of the lower wafer W1′ may diffuse to each other, so that metal-to-metal bonds also occurs therebetween. Afterwards, the resulting bonds between the upper dies 200 and the lower wafer W1′ includes metal to metal bonds and dielectric to dielectric bonds. The dimensions of the upper connectors 240 of the upper dies 200 and the lower connectors 1400 of the lower wafer W1′ may be similar. For example, widths of the upper connectors 240 may be substantially the same as width of the corresponding lower connectors 1400 so that after bonding, the lower connectors 1400 and the corresponding upper connectors 240 are pitch-matched. In alternative embodiments, the dimensions of the upper connectors 240 of the upper dies 200 and the corresponding lower connectors 1400 of the lower wafer W1′ are different. The dimensions of the upper connectors 240 of the upper dies 200 may be greater than that of the corresponding lower connectors 1400 of the lower wafer W1′. In alternative embodiments, the dimensions of the lower connectors 1400 of the lower wafer W1′ may be greater than that of the corresponding upper connectors 240.

Referring to FIG. 7, after bonding the upper dies 200 with the lower wafer W1′, an encapsulating material 3000 is formed over the lower wafer W1′ to laterally encapsulate the upper dies 200. In some embodiments, the encapsulating material 3000 is formed to cover the lower wafer W1′ and each of the upper dies 200. For example, the encapsulating material 3000 is formed over the wafer bonding surface WS1 of the lower wafer W1′ and wraps the upper dies 200. The encapsulating material 3000 may fill the gaps G between the adjacent upper dies 200 so that the encapsulating material 3000 covers the sidewalls SW and the rear surfaces RS′ of the upper dies 200. In some embodiments, the encapsulating material 3000 includes inorganic material (e.g., silicon dioxide, Si—O—N, Si—C—N, Si—C—O, or the like), organic material (e.g., epoxy, polyimide (PI), polybenzoxazole (PBO), or the like), or the mixture of inorganic and organic materials (e.g., the mixture of silicon dioxide and epoxy, or the like). The encapsulating material 3000 may be referred to as “gap-fill dielectric”. In alternative embodiments, the encapsulating material 3000 includes a molding compound, a molding underfill (MUF), a resin, or the like. The encapsulating material 3000 may be formed through chemical vapor deposition (CVD), plasma-enhanced chemical vapor deposition (PECVD), atomic layer deposition (ALD), or other suitable techniques.

Subsequently, the encapsulating material 3000 is partially removed to reveal the upper dies 200 so as to form the dielectric encapsulation 3000. For example, after forming the encapsulating material 3000, a planarization process may be performed on the encapsulating material 3000. In some embodiments, the planarization process includes a mechanical grinding process and/or a chemical mechanical polishing (CMP) process, or other applicable processes. In some embodiments, the planarization process is performed on the encapsulating material 3000 and the rear surfaces RS of the upper dies 200, thereby obtaining a substantially planar surface topography. For example, the encapsulating material 3000 is grinded to form a top surface 3000s of the encapsulating material 3000 and the rear surfaces RS of the upper dies 200 is also grinded to form planarized rear surfaces RS. The surface roughness of the planarized rear surfaces RS of the upper dies 200 and the top surface 3000s of the encapsulating material 3000 may be less than about 0.5 μm. In some embodiments, the planarized rear surfaces RS of the upper dies 200 are substantially coplanar with the top surface 3000s of the encapsulating material 3000. The upper dies 200 may be grinded until the through semiconductor vias 212 are revealed by the planarized rear surfaces RS of the upper dies 200 for further electrical connection.

In some embodiments, after the planarization process, the through semiconductor vias 212 may penetrate through the semiconductor substrate 210 so that the through semiconductor vias 212 allow electrical communication between the front side and the back side of the corresponding upper dies 200. In some other embodiments, after the through semiconductor vias 212 are revealed, the semiconductor substrate 210 of the upper dies 200 may be further grinded to render desired thicknesses of the upper dies 200. In some other embodiments, during thinning the encapsulating material 3000, the lower substrate 1100 of the lower wafer W1′ may be thinned at the same time, thereby reducing the overall thickness of the structure.

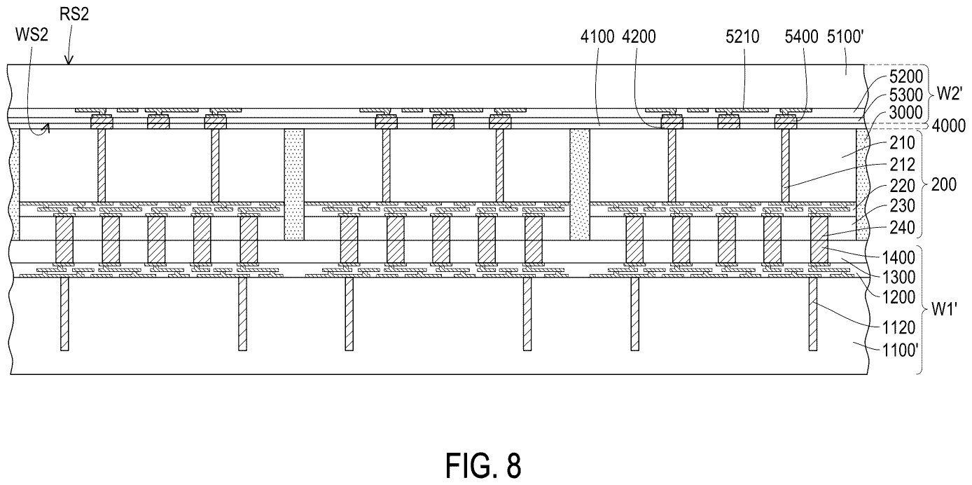

Referring to FIG. 8, a bonding layer 4000 is formed on the upper dies 200 and the encapsulating material 3000. In some embodiments, the bonding layer 4000 includes a dielectric layer 4100 and conductive features 4200 laterally wrapped by the dielectric layer 4100. For example, a dielectric material (not shown) may be formed over the planarized rear surfaces RS of the upper dies 200 and the top surface 3000s of the encapsulating material 3000 by spin-coating, laminating, or other suitable deposition techniques. Next, the dielectric material is patterned to form the dielectric layer 4100 having a plurality of openings (not shown) using, for example, lithography and etching processes, or other suitable methods. The openings of the dielectric layer 4100 may expose at least a portion of the through semiconductor vias 212 of the upper dies 200 on the planarized rear surface RS. Subsequently, a conductive material may be formed in the openings of the dielectric layer 4100 so as to form the conductive features 4200 using plating, sputtering, or other suitable depositing process. The conductive features 4200 formed on the planarized rear surfaces RS may be electrically and physically connected to the through semiconductor vias 212 of the upper dies 200 for further electrical connection. The conductive features 4200 of the bonding layer 4000 may be formed within the area of the planarized rear surfaces RS. In some alternative embodiments, the conductive features 4200 of the bonding layer 4000 may be formed to expand wider than the area of the planarized rear surfaces RS so as to reroute electrical signals of the upper dies 200.

Then, a semiconductor wafer W2′ is bonded to a backside of the upper substrate 210 of the upper die 200 through the bonding layer 4000. In some embodiments, the semiconductor wafer W2′ includes a substrate 5100', an interconnect structure 5200 formed over the substrate 5100′, a dielectric layer 5300 formed over the interconnect structure 5200, and a plurality of conductive connectors 5400 embedded in the dielectric layer 5300. The substrate 5100′ may be a silicon wafer, a semiconductor substrate (e.g., a bulk semiconductor which may be doped or undoped), or other suitable substrates (e.g., a multi-layered, gradient substrate, etc.). The semiconductor material of the substrate 5100′ may be similar with that of the lower substrate 1100 of the lower wafer W1′. In some embodiments, the substrate 5100′ may include various electrical components (e.g., transistors, capacitors, resistors, inductors, combinations of these, or the like) and metallization patterns interconnected each other to perform one or more functions.

In some embodiments, the interconnect structure 5200 includes a plurality of conductive patterns 5210. In some embodiments, the conductive conductors 5400 are laterally wrapped by the dielectric layer 5300. The conductive conductors 5400 may include bonding pads electrically coupled to the conductive patterns 5210 of the second interconnect structure 5200. The materials of the conductive conductors 5400 and the dielectric layer 5300 may be similar to that of the lower connectors 1400 and the bonding layer 1300 of the lower wafer W1′. In some embodiments, at least a portion of the conductive conductors 5400 are revealed by the dielectric layer 5300. For example, the top surfaces of the conductive conductors 5400 and the top surface of the dielectric layer 5300 are substantially level and may be collectively referred to as a wafer bonding surface WS2.

In some embodiments, the semiconductor wafer W2′ is attached to the bonding layer 4000 by metal to metal bonding and/or dielectric to dielectric bonding. For example, a pre-bonding process may be performed, where the wafer bonding surface WS2 faces toward the bonding layer 4000 and the conductive conductors 5400 of the semiconductor wafer W2′ and the conductive features 4200 of the bonding layer 4000 are aligned. The semiconductor wafer W2′ and the underlying structure are pressed against together to form weak bonds. After the pre-bonding process, an annealing process may be performed to strengthen the weak bonds and form a fusion bond. During the annealing, the H of the OH bonds is outgassed, thereby forming Si—O—Si bonds between the semiconductor wafer W2′ and the underlying structure, thereby strengthening the bonds. The direct metal-to-metal bonding may also occur between the conductive conductors 5400 of the semiconductor wafer W2′ and the conductive features 4200 of the bonding layer 4000. Accordingly, the resulting bond includes the Si—O—Si bonds and metal-to-metal direct bonds. In some embodiments, the bonding of the structure shown in FIG. 8 may be performed at the wafer-to-die-to-wafer level.

In some other embodiments, the semiconductor wafer W2′ may be a supporting substrate without any active devices. In such embodiment, the upper dies 200 may not include any through semiconductor vias 212, and the bonding layer 4000 may be an adhesive layer for bonding the semiconductor wafer W2′ to the upper dies 220 and the encapsulating material 3000.

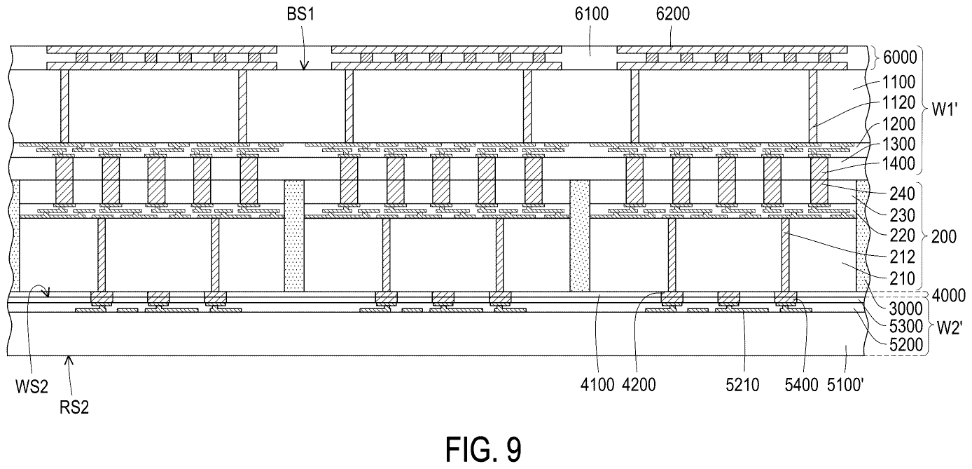

Then, referring to FIG. 9, after bonding the semiconductor wafer W2', the resulting structure may then be overturned (e.g., flipped upside down) for further processing onto the back surface BS1 of the lower wafer W1'. For example, a thinning process is performed on the back surface BS1 of the lower wafer W1′ so that the through semiconductor vias 1120 of the lower wafer W1′ are exposed by the back surface BS1. The lower substrate 1100′ may be thinned until the through semiconductor vias 1120 are revealed by the back surface BS1 of the lower wafer W1′ using a mechanical grinding process and/or a CMP process, or other suitable processes. Accordingly, after the thinning process, the through semiconductor vias 1120 extend through the lower substrate 1100 of the lower wafer W1′. In some embodiments, after exposing the through semiconductor vias 1120, a circuitry structure 6000 including one or more dielectric layers 6100 and one or more metallization patterns 6200 may be formed over the back surface BS1 of the lower wafer W1′. The metallization patterns 6200 embedded in the dielectric layer 6100 may be in electrical and physical contact with the through semiconductor vias 1120 of the lower wafer W1′.

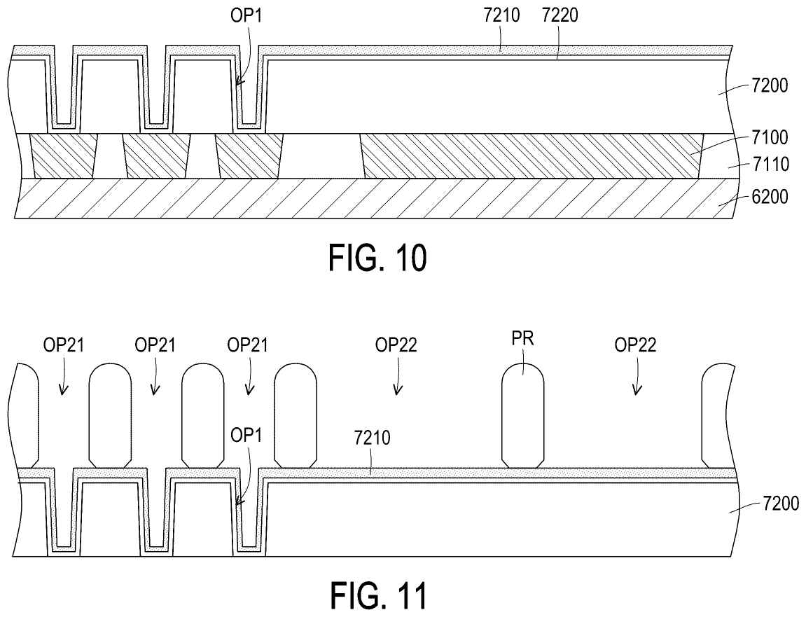

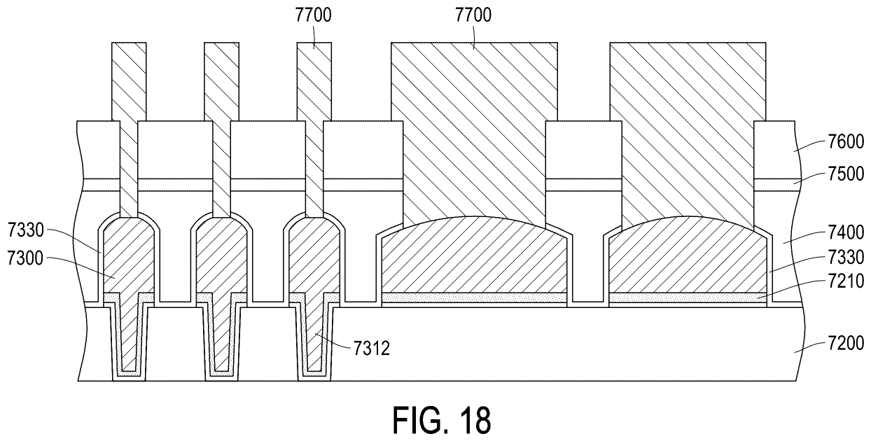

FIG. 10 to FIG. 18 illustrate partial-enlarged cross sectional views of a semiconductor package for showing the formation of lower backside copper pads 7300 and conductive bumps 7700 (see FIG. 18) over the backside of the lower wafer W1′(e.g., the resulting structure shown in FIG. 9). For purpose of clarity and simplicity, detail description of same or similar features may be omitted, and the same or similar reference numbers denote the same or like components.

Referring to FIG. 10, in some embodiments, a plurality of conductive features 7100 such as conductive contacts, conductive vias, and conductive lines are formed over the circuitry structure 6000. The conductive features 7100 are formed in an interlayer dielectric layer 7110 and electrically connected to the metallization patterns 6200 of the circuitry structure 6000. Afterwards, a first passivation layer 7200 is formed over the conductive features 7100 and the interlayer dielectric layer 7110. In some embodiments, the first passivation layer 7200 is made of silicon nitride, polyimide (PI), polybenzoxazole (PBO), another suitable material, or a combination thereof. The first passivation layer 7200 may be a single layer or include multiple sub-layers. Then, the first passivation layer 7200 is patterned to form an opening OP1 that exposes a part of the conductive features 7100. The formation of the first passivation layer 7200 may involve deposition, patterning, and planarization processes, etc.

Then, a diffusion barrier layer 7220 and a seed layer 7210 may be formed over the first passivation layer 7200 and cover the opening OP1 om a conformal manner with the diffusion barrier layer 7220 in contact with the conductive features 7100, in accordance with some embodiments. The diffusion barrier layer 7220 may be a titanium layer, a titanium nitride layer, a tantalum layer, a tantalum nitride layer, or the like. The materials of the seed layer 7210 may include copper or copper alloys, or the like. However, other metals, such as silver, gold, aluminum, and combinations thereof, may also be included. In some embodiments, the diffusion barrier layer 7220 and the seed layer 7210 are formed using sputtering.

Then, referring to FIG. 11, a photoresist layer PR is formed over the first passivation layer 7200. To be more specifically, the photoresist layer PR is formed on the seed layer 7210 and includes a plurality of openings OP21, OP22 to expose the corresponding portions of the seed layer 7210 underneath. In the depicted embodiment, the photoresist layer PR at least exposes regions corresponding to the openings OP1 of the first passivation layer 7200. For example, the photoresist layer PR includes a plurality of openings OP21 and OP22, wherein the openings OP21 expose portions of the seed layer 7210 that covers the openings OP1, and the openings OP22 expose portions of the seed layer 7210 on the (planar) top surface of the first passivation layer 7200. In some embodiment, the photoresist layer PR is a photosensitive layer operable to be patterned by an exposure process, which initiates a series of photochemical reactions in the photoresist layer PR. The photoresist layer PR may include any suitable photosensitive resist material, and in many embodiments, the photoresist layer PR includes a resist material sensitive to radiation (e.g., UV light, deep ultraviolet (DUV) radiation, and/or EUV radiation). The photoresist layer PR may include a single-layer material or multiple material layers.

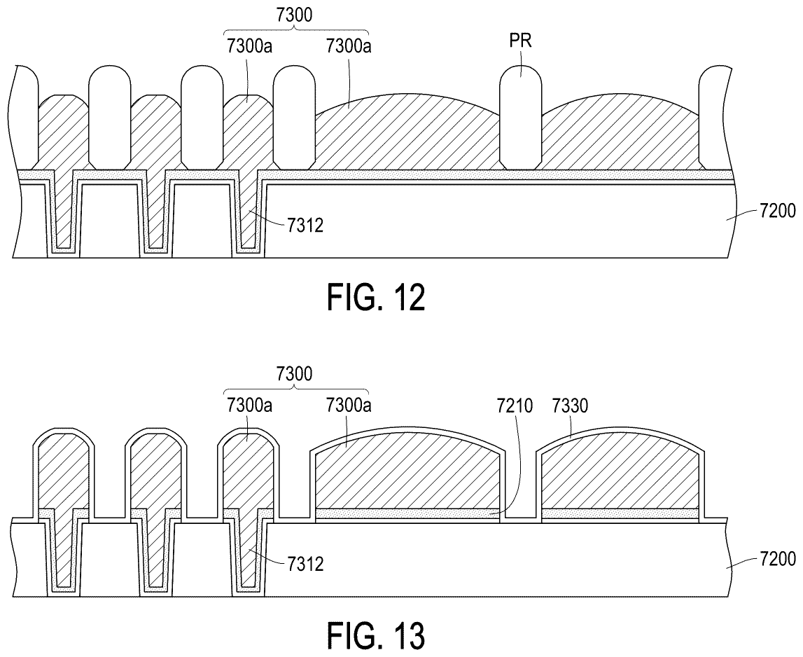

Then, referring to FIG. 11 and FIG. 12, a copper electroplating process is performed through the photoresist layer PR to form a patterned copper layer including a plurality of lower backside copper pads 7300 (i.e., conductive pads on the backside of the lower substrate 1100 of the lower wafer W1′). In detail, the patterned copper layer is formed on the first passivation layer 7200 over the backside BS1 of the lower substrate 1100 as shown in FIG. 9, and includes the lower backside copper pads 7300a and 7300b, wherein the lower backside copper pads 7300a are defined by filling conductive material such as copper in the openings OP21 and the lower backside copper pads 7300b are defined by filling conductive material such as copper in the openings OP22. The lower backside copper pads 7300a that fills the openings OP21 further fills the opening OP1 underneath to form conductive vias 7312.

In the embodiment, the lower backside copper pads 7300 is aluminum free. That is, aluminum is replaced with copper to be adopted as material of the backside conductive pads to provide better leveling of the deposit across irregularities (e.g., opening OP1) on the surface to be deposited. In an embodiment, an electroplating solution for plating copper may have copper sulfate (CuSO₄) and sulphuric acid (H₂SO₄). The sulphuric acid disassociates the copper ions from the copper sulfate, allowing the copper sulfate to migrate to the substrate and form copper layer. The rate of copper plating is much faster than the rate of aluminum plating. Accordingly, when copper electroplating process is performed to fill openings (such as the openings OP1) over a surface to be plated, the plated copper layer can smooth over the openings on the surface instead of leaving a concave on the upper surface corresponding to the opening. That is, each of lower backside copper pads 7300a and 7300b includes a non-concave upper (bonding) surface to be bonded with subsequently formed conductive bumps (e.g., the conductive bumps 7700 in FIG. 18). In some embodiments, the non-concave upper surface of each of the lower backside copper pads 7300a and 7300b can be a substantially planar surface or a curvy convex surface.

Then, referring to FIG. 12 and FIG. 13, the photoresist layer PR is removed, and an etching stop layer 7330 is formed on the first passivation layer 7200 over the backside of the lower substrate. The etching stop layer 7330 covers the upper surface of the first passivation layer 7200 and covers the lower backside conductive pads 7300 in a conformal manner. In the current embodiment, the etch stop layer 7330 may include silicon nitride (SiN), silicon oxynitride (SiON), silicon carbon nitride (SiCN), Carbon-Doped Oxide (CDO), carbon incorporated silicon oxide (SiOC) or Ornithine decarboxylase (ODC), Nitrogen-Doped silicon Carbide (NDC), or the like, having a thickness of about 600 Å formed by a PECVD process, although other suitable processes can be also used.

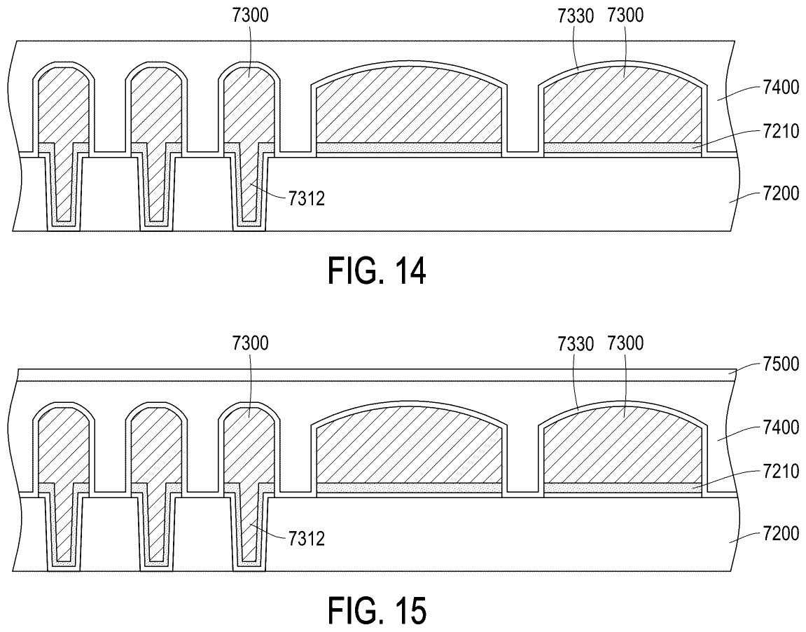

Then, referring to FIG. 14 and FIG. 15, one or more dielectric layers 7400, 7500 are formed over the first passivation layer 7200 over the backside of the lower substrate. The dielectric layers 7400, 7500 cover the etching stop layer 7330 and the lower backside conductive pads 7300. In the current embodiment, the dielectric layer 7400 deposited over the first passivation layer 7200 may be an oxide layer such as a semiconductor oxide, which includes silicon oxide (SiO₂), silicon oxide nitride (SiON), aluminum silicon oxide (AlSiO), or another suitable oxide material, and it can be deposited by chemical oxidation, thermal oxidation, atomic layer deposition (ALD), or other suitable methods. The dielectric layer 7500 deposited over the dielectric layer 7400 may be a nitride layer such as a semiconductor oxide, which includes silicon nitride, or another suitable nitride material, and it can be deposited by low-temperature CVD, plasma-enhanced CVD (PECVD) methods, or other suitable methods. In some embodiments, a thickness of the dielectric layer 7500 is thinner than a thickness of the dielectric layer 7400, but the disclosure is not limited thereto.

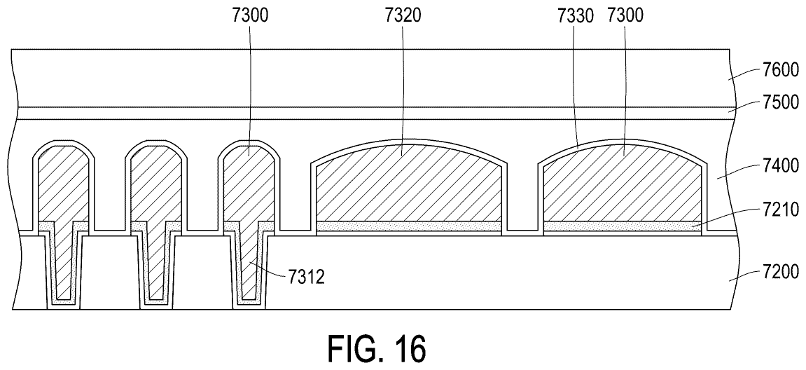

Then, referring to FIG. 16, a second passivation layer 7600 is formed over the dielectric layers 7400, 7500. In some embodiments, the second passivation layer 7600 is made of silicon nitride, polyimide (PI), polybenzoxazole (PBO), another suitable material, or a combination thereof. The second passivation layer 7600 may be a single layer or may include multiple sub-layers.

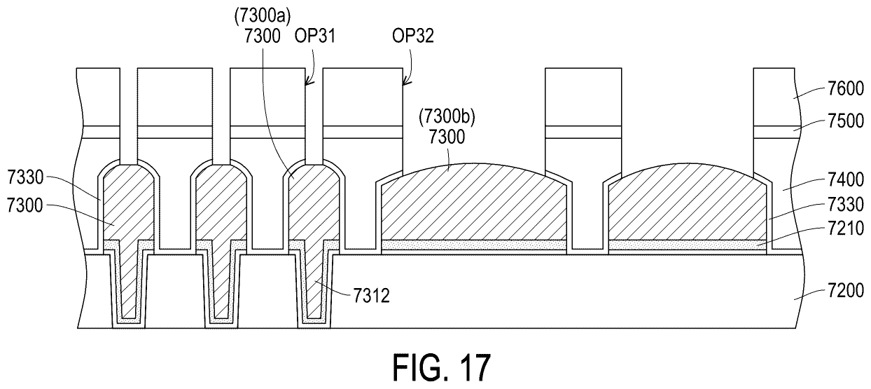

Then, referring to FIG. 17, a plurality of openings OP31, OP32 are formed over the one or more dielectric layers 7400, 7500, and the second passivation layer 7600 to reveal upper surfaces of the lower backside conductive pads 7300 respectively. The openings OP31 are formed to expose the upper surfaces of the lower backside conductive pads 7300a that connecting the conductive vias 7312. The openings OP32 are formed to expose the upper surfaces of the lower backside conductive pads 7300b formed over the planar top surface of the first passivation layer 7200. The diameter of the opening OP32 may be greater than the diameter of the opening OP31. The etch stop layer 7300 is etched through during the formation of the openings OP31, OP32, and reveals the underlying lower backside copper pads 7300a, 7300b. By replacing the aluminum with copper as the material of the lower backside copper pads 7300, the etch stop layer 7300 is added to prevent the etching from damaging the copper pads underneath.

Then, referring to FIG. 18, a plurality of conductive bumps 7700 are formed in the openings OP31, OP32 to fill the openings OP31, OP32 in the dielectric layers 7400, 7500, and the second passivation layer 7600, in accordance with some embodiments. The conductive bumps 7700 are formed over and in contact with the lower backside copper pads 7300 respectively and electrically connected to the lower backside copper pads 7300. In some embodiments, the conductive bumps 7700 includes micro bumps, but not limited thereto. In some embodiments, an under bump metallization (not shown) may be formed over the sidewalls and bottom of the openings OP31, OP32 before the formation of the conductive bump 7700. In some embodiments, the UBM layer includes chromium (Cr), copper (Cu), gold (Au), titanium (Ti), tungsten (W), another suitable material, or a combination thereof.

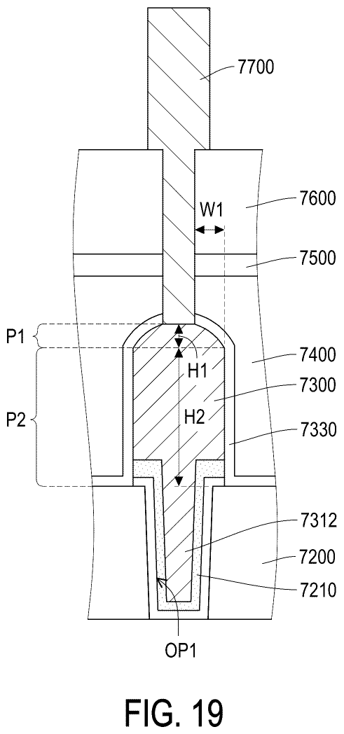

FIG. 19 illustrates a partial-enlarged cross sectional view of a semiconductor package according to some embodiments of the present disclosure. Referring to FIG. 18 and FIG. 19, from a structural point of view, the etching stop layer 7330 at least laterally encapsulates a side surface of each of the lower backside copper pads 7300, and reveals a non-concave upper surface of the lower backside copper pad 7300 to be bonded with the conductive bumps 7700. The first dielectric layer 7400 covers the etching stop layer 7330 and laterally surrounds the conductive bumps 7700. In detail, each of the lower backside copper pads 7300 includes a dome portion P1 bonded to respective one of the conductive bumps 7700 and a cylinder portion P2 connected to the dome portion P1. The etching stop layer 7330 covers the cylinder portion P2 and a part of the dome portion P1, but reveals an upper portion of the dome portion P1. A ratio of a height H1 of the dome portion P1 to a height H2 of the cylinder portion P2 substantially ranges from about ⅓ to about 1/50. The horizontal width W1 that the etching stop layer 7330 covers the dome portion P1 may substantially ranges from about 3 μm to about 20 μm. It is noted that the recitation of a particular numerical value or value range herein is understood to include or be a recitation of an approximate numerical value or value range (e.g., within +/−20%, +/−10%, or +/−5%). Similarly, the recitation of equivalence, essential equivalence, or approximate equivalence is understood to encompass actual equality as well as essential or approximate equivalence (e.g., identical to within +/−20%, +/−10%, or +/−5%).

Accordingly, the backside conductive pads 7300 is made of copper, so as to provide better leveling of the deposit across irregularities (e.g., opening OP1) on the first passivation layer 7200. That is, each of the backside copper pads 7300 has a non-concave upper surface even after filling the openings OP1 of the first passivation layer 7200. Therefore, cracks of the passivation layer 7600 due to having concaves on the upper surfaces of the backside conductive pads can be avoided, so as to reduce or prevent moisture from penetrating into the integrated circuits. Accordingly, reliability of the semiconductor package 10 can be significantly improved. Moreover, layout flexibility of the conductive vias 7312 (formed by filling the openings OP1 of the first passivation layer 7200) and the conductive bumps 7700 can also be improved, and fine pitch requirements can be met.

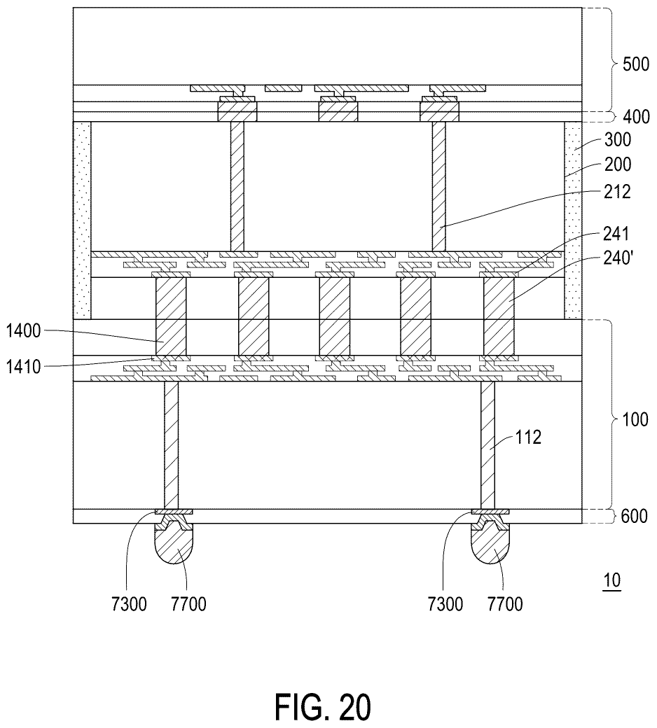

With now reference to FIG. 9 and FIG. 20, after forming the conductive bumps 7700, a singulation process may be performed to cut the lower wafer W1′, the encapsulating material 3000, and the semiconductor wafer W2′. In some embodiments, the singulation process involves dicing with a rotating blade or a laser beam. The dicing or singulation process includes a laser cutting process, a mechanical cutting process, or other suitable processes. In some embodiments, during the singulation process, the lower wafer W1′, the encapsulating material 3000, and the semiconductor wafer W2′ may be cut off along scribe lines so as to be divided into a plurality of semiconductor package 10 as shown in FIG. 20.

Accordingly, the semiconductor package 10 includes a multi-leveled IC component stack having at least one discrete die (e.g., at least one upper die 200) packaging therein. In some embodiments, the semiconductor package 10 may be referred to as the system on integrated circuit (SoIC) package. For example, the semiconductor package 10 includes a lower die 100 (e.g., singulated from the lower wafer W1′), the upper die 200 stacked on and electrically connected to the lower die 100, an encapsulating material 300 (e.g., singulated from the encapsulating material 3000) laterally encapsulating the upper die 200, a bonding layer 400 (e.g., singulated from the bonding layer 4000) disposed between the upper die 200 and a semiconductor die 500 (e.g., singulated from the semiconductor wafer W2′) stacked on and electrically connected to the upper die 200, a circuit layer 600 (e.g., singulated from the circuitry structure 6000) stacked on the lower die 100 and electrically connected to the through semiconductor vias 112 of the lower die 100, a plurality of backside copper pads 7300 formed on the circuit layer 600, and a plurality of conductive bumps 7700 formed on the backside copper pads 7300 and electrically connected to the through semiconductor vias 112 of the lower die 100 through the circuit layer 600. In some embodiments, the pitch between adjacent two of the through semiconductor vias 112 may be substantially equal to or smaller than about 6 μm, and the pitch between adjacent two of the conductive bumps 7700 may be substantially equal to or smaller than about 35 μm with the redistribution of the backside conductive copper pads 7300. In some embodiments, the through semiconductor vias 112 of the lower die 100 and the through semiconductor vias 212 of the upper die 200 are electrically connected. The semiconductor package 10 may perform a variety of electrical functions necessary for different applications. It should be appreciated that the semiconductor package 10 can further be packaged to form a package-on-package (PoP) structure or system-in-package (SiP) structure using suitable packaging techniques. The applications of the semiconductor package 10 are not limited in the disclosure.

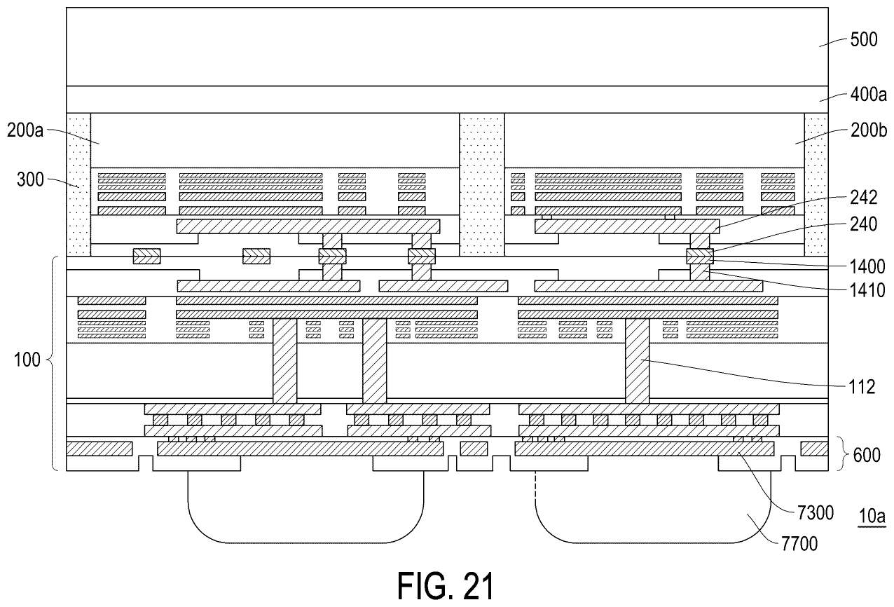

FIG. 21 illustrates a cross sectional view of a semiconductor package according to some embodiments of the present disclosure. It is noted that the semiconductor package 10a shown in FIG. 21 contains many features same as or similar to the semiconductor packages disclosed in the previous embodiments. For purpose of clarity and simplicity, detail description of same or similar features may be omitted, and the same or similar reference numbers denote the same or like components.

Referring to FIG. 21, in accordance with some embodiments of the disclosure, a plurality of upper dies 200a, 200b are disposed on the lower die 100 and laterally encapsulated by the encapsulating material 300. It is noted that two upper dies 200a, 200b are illustrated herein, but more upper dies may be disposed on the lower die 100 in the semiconductor package 10a. In the current embodiments, the upper dies 200a, 200b may both be device dies with active devices formed therein. For example, the upper dies 200a, 200b may be logic dies (e.g., central processing unit (CPU), graphics processing unit (GPU), microcontroller, etc.), memory dies (e.g., dynamic random access memory (DRAM) dies, static random access memory (SRAM) dies, etc.), power management dies (e.g., power management integrated circuit (PMIC) dies), radio frequency (RF) dies, sensor dies, micro-electro-mechanical-system (MEMS) dies, the like, or a combination thereof. In certain embodiments, the processing, memory, and/or electronic control functionality may be integrated on the same integrated circuit component.

In the current embodiments, the supporting substrate 500 may be a glass carrier substrate, a ceramic carrier substrate, a silicon wafer, or the like. In such embodiments, the bonding layer 400a includes a silicon-containing dielectric material such as silicon oxide or silicon nitride, and may be formed using CVD, PVD, spin-coating, or the like. In some embodiments, the pitch between adjacent two of the through semiconductor vias 112 may be substantially equal to or smaller than about 6 μm, and the pitch between adjacent two of the conductive bumps 7700 may be substantially equal to or smaller than about 35 μm with the redistribution of the backside conductive copper pads 7300.

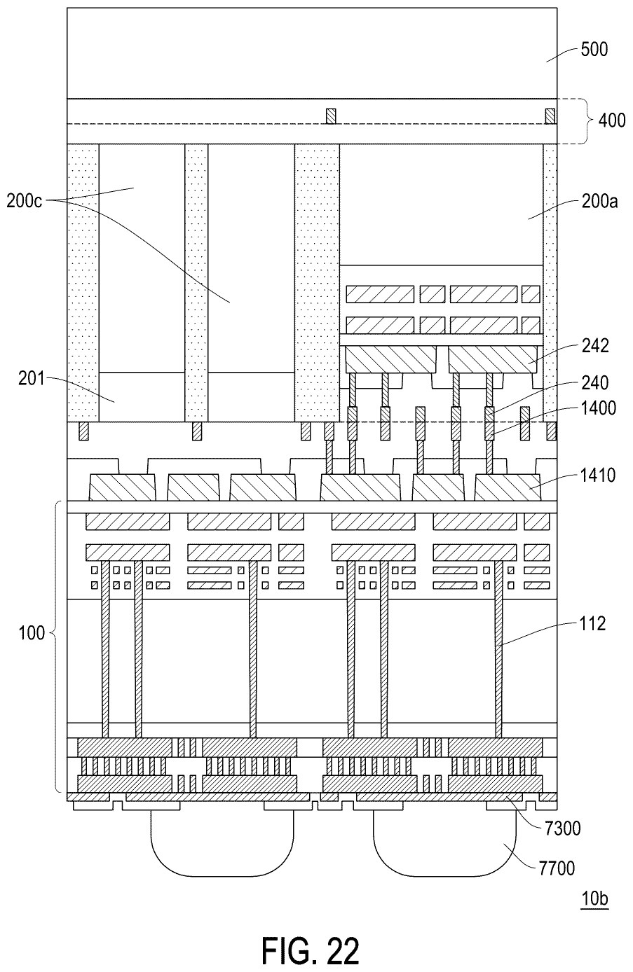

FIG. 22 illustrates a cross sectional view of a semiconductor package according to some embodiments of the present disclosure. It is noted that the semiconductor package 10a shown in FIG. 22 contains many features same as or similar to the semiconductor packages disclosed in the previous embodiments. For purpose of clarity and simplicity, detail description of same or similar features may be omitted, and the same or similar reference numbers denote the same or like components.

Referring to FIG. 22, in accordance with some embodiments of the disclosure, a plurality of upper dies 200a, 200c are disposed on the lower die 100 and laterally encapsulated by the encapsulating material 300. In the current embodiments, the upper dies includes at least one device die 200a electrically connected to the lower die 100 and at least one dummy die 200c electrically insulated from the lower die 100. The upper die 200a may be a logic die (e.g., central processing unit (CPU), graphics processing unit (GPU), microcontroller, etc.), a memory die (e.g., dynamic random access memory (DRAM) die, static random access memory (SRAM) die, etc.), power management die (e.g., power management integrated circuit (PMIC) die), radio frequency (RF) die, sensor die, micro-electro-mechanical-system (MEMS) die, the like, or a combination thereof. In certain embodiments, the processing, memory, and/or electronic control functionality may be integrated on the same integrated circuit component.

One or more dummy dies 200c may be applied in the semiconductor package 10b in order to reduce CTE mismatch and improve the warpage profile of the resulting semiconductor package 10b. A number of the dummy dies 200c, and a size of the dummy dies 200c may be determined according to the requirements of the packages. While the device die 200a may be functional dies containing devices, circuits, and the like, the dummy dies 200c may be non-functional dies and in some embodiments may not contain any devices and/or functional electrical circuits. The dummy dies 200c may include any suitable material for adjusting the effective CTE of the semiconductor package 10b to a desired level. The dummy dies 200c may include a material for lowering the effective CTE of the semiconductor package 10b, such as silicon, glass or ceramic. In other embodiments, the dummy dies 200c may include a material for raising the effective CTE, such as copper or a polymer. In some embodiments, the dummy dies 200c are composed of or includes the same materials that are included in the device die 200a. For example, in some embodiments dummy dies 200c may be selected so that an effective CTE of the dummy dies 200c are the same or similar to an effective CTE of the device die 200a. In some embodiments, the device dies 200a are bonded to the lower die 100 through metal to metal bonding and/or dielectric to dielectric bonding, and the dummy dies 200c may be attached to the lower die 100 through an adhesive 201 such as die attach film (DAF), or the like.

In the current embodiments, the semiconductor die 500 may be a supporting substrate, which is bonded to a backside of the second dies 200a and 200b and the encapsulating material 300 through a bonding layer 400a. The supporting substrate 500 may be a glass carrier substrate, a ceramic carrier substrate, a silicon wafer, or the like. In some embodiments, passive devices may be formed in the semiconductor die 500. In such embodiments, the bonding layer 400a includes a silicon-containing dielectric material such as silicon oxide or silicon nitride, and may be formed using CVD, PVD, spin-coating, or the like.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a first die, a plurality of conductive bumps and a second die. The first die includes a first substrate, a plurality of first through vias extending through the first substrate, a plurality of copper pads over a backside of the first substrate, wherein each of the plurality of copper pads is aluminum free, and a plurality of first connectors over a front side of the first substrate. The plurality of conductive bumps are disposed on the plurality of copper pads respectively. The second die is bonded over the first die and includes a second substrate, and a plurality of second connectors over a front side of the second substrate and directly bonded to the plurality of first connectors respectively. In one embodiment, the first die further comprises a plurality of first conductive pads where the plurality of first connectors are disposed and the second die further comprises a plurality of second conductive pads where the plurality of second connectors are disposed, and each of the plurality of first conductive pads and the plurality of second conductive pads comprises aluminum. In one embodiment, each of the plurality of copper pads comprises a non-concave bonding surface that is bonded with respective one of the plurality of conductive bumps. In one embodiment, the first die further comprises an etch stop layer at least laterally encapsulating a side surface of each of the plurality of copper pads. In one embodiment, the first die further comprises a dielectric layer covering the etch stop layer and laterally surrounding the plurality of conductive bumps. In one embodiment, the semiconductor package further includes an encapsulating material over the first die and laterally encapsulating the second die. In one embodiment, the semiconductor package further includes a dummy die bonded over the first die and laterally encapsulated by the encapsulating material. In one embodiment, the semiconductor package further includes a supporting substrate bonded to a backside of the second die. In one embodiment, each of the plurality of copper pads comprises a dome portion bonded to respective one of the plurality of conductive bumps and a cylinder portion connected to the dome portion.

In accordance with some embodiments of the disclosure, a semiconductor package includes a lower die, a plurality of lower connectors and a plurality of upper dies. The lower die includes a lower substrate, a plurality of lower backside conductive pads over a backside of the lower substrate, an etch stop layer laterally encapsulating a side surface of each of the plurality of lower backside conductive pads, and a plurality of lower connectors over a front side of the lower substrate. The plurality of conductive bumps are disposed on the plurality of lower backside conductive pads respectively. The plurality of upper dies are bonded over the lower die and includes an upper substrate a plurality of upper connectors over a front side of the upper substrate and directly bonded to the plurality of lower connectors respectively. In one embodiment, the lower die further comprises a plurality of lower front side conductive pads where the plurality of lower connectors are disposed, the upper die further comprises a plurality of upper front side conductive pads where the plurality of upper connectors are disposed. In one embodiment, each of the plurality of lower backside conductive pads is aluminum free, and each of the plurality of lower front side conductive pads and the plurality of upper front side conductive pads comprises aluminum. In one embodiment, the lower die further comprises a dielectric layer covering the etch stop layer and laterally surrounding the plurality of conductive bumps. In one embodiment, the plurality of upper dies comprises a device die electrically connected to the lower die and a dummy die. In one embodiment, each of the plurality of copper pads comprises a dome portion bonded to respective one of the plurality of conductive bumps and a cylinder portion connected to the dome portion, and the etch stop layer covers the cylinder portion and a part of the dome portion.

In accordance with some embodiments of the disclosure, a manufacturing method of a semiconductor package includes the following steps: forming an upper connectors over a front side of an upper substrate and form an upper die; forming a plurality of lower connectors over a front side of a lower substrate, wherein the lower substrate comprises a plurality of lower through vias; directly bonding the plurality of upper connectors to the plurality of lower connectors; performing a copper electroplating process to form a plurality of lower backside copper pads over a backside of the lower substrate; and forming a plurality of conductive bumps over the plurality of lower backside copper pads respectively. In one embodiment, forming the plurality of conductive bumps over the plurality of lower backside copper pads respectively further includes: forming an etch stop layer over the backside of the lower substrate to cover the plurality of lower backside conductive pads; forming a dielectric layer over the backside of the lower substrate to cover the etch stop layer and the plurality of lower backside conductive pads; forming a plurality of openings over the dielectric layer to reveal upper surfaces of the plurality of lower backside conductive pads respectively; and forming the plurality of conductive bumps in the plurality of openings. In one embodiment, the manufacturing method of the semiconductor package further includes forming an encapsulating material to laterally encapsulate the upper die. In one embodiment, the manufacturing method of the semiconductor package further includes bonding a supporting substrate to a backside of the upper substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die comprising:
a first substrate;
a plurality of first through vias extending through the first substrate;
a plurality of copper pads over a backside of the first substrate, wherein each of the plurality of copper pads is aluminum free; and
a plurality of first connectors over a front side of the first substrate;
a plurality of conductive bumps disposed on the plurality of copper pads respectively; and
a second die bonded over the first die and comprising a second substrate, and a plurality of second connectors over a front side of the second substrate and directly bonded to the plurality of first connectors respectively.

2. The semiconductor package as claimed in claim 1, wherein the first die further comprises a plurality of first conductive pads where the plurality of first connectors are disposed and the second die further comprises a plurality of second conductive pads where the plurality of second connectors are disposed, and each of the plurality of first conductive pads and the plurality of second conductive pads comprises aluminum.

3. The semiconductor package as claimed in claim 1, wherein each of the plurality of copper pads comprises a non-concave bonding surface that is bonded with respective one of the plurality of conductive bumps.

4. The semiconductor package as claimed in claim 1, wherein the first die further comprises an etch stop layer at least laterally encapsulating a side surface of each of the plurality of copper pads.

5. The semiconductor package as claimed in claim 4, wherein the first die further comprises a dielectric layer covering the etch stop layer and laterally surrounding the plurality of conductive bumps.

6. The semiconductor package as claimed in claim 1, further comprising an encapsulating material over the first die and laterally encapsulating the second die.

7. The semiconductor package as claimed in claim 6, further comprising a dummy die bonded over the first die and laterally encapsulated by the encapsulating material.

8. The semiconductor package as claimed in claim 1, further comprising a supporting substrate bonded to a backside of the second die.

9. The semiconductor package as claimed in claim 1, wherein each of the plurality of copper pads comprises a dome portion bonded to respective one of the plurality of conductive bumps and a cylinder portion connected to the dome portion.

10. A semiconductor package, comprising:
a lower die comprising:
a lower substrate;
a plurality of lower backside conductive pads over a backside of the lower substrate;
an etch stop layer laterally encapsulating a side surface of each of the plurality of lower backside conductive pads; and
a plurality of lower connectors over a front side of the lower substrate;
a plurality of conductive bumps disposed on the plurality of lower backside conductive pads respectively; and
a plurality of upper dies bonded over the lower die and comprising an upper substrate a plurality of upper connectors over a front side of the upper substrate and bonded to the plurality of lower connectors respectively.

11. The semiconductor package as claimed in claim 10, wherein the lower die further comprises a plurality of lower front side conductive pads where the plurality of lower connectors are disposed, the upper die further comprises a plurality of upper front side conductive pads where the plurality of upper connectors are disposed.

12. The semiconductor package as claimed in claim 11, wherein each of the plurality of lower backside conductive pads is aluminum free, and each of the plurality of lower front side conductive pads and the plurality of upper front side conductive pads comprises aluminum.

13. The semiconductor package as claimed in claim 10, wherein the lower die further comprises a dielectric layer covering the etch stop layer and laterally surrounding the plurality of conductive bumps.

14. The semiconductor package as claimed in claim 10, wherein the plurality of upper dies comprises a device die electrically connected to the lower die and a dummy die.

15. The semiconductor package as claimed in claim 10, wherein each of the plurality of copper pads comprises a dome portion bonded to respective one of the plurality of conductive bumps and a cylinder portion connected to the dome portion, and the etch stop layer covers the cylinder portion and a part of the dome portion.

16. The semiconductor package as claimed in claim 10, further comprising a supporting substrate bonded to the plurality of upper dies.

17. A manufacturing method of a semiconductor package, comprising:
forming an upper connectors over a front side of an upper substrate and form an upper die;
forming a plurality of lower connectors over a front side of a lower substrate, wherein the lower substrate comprises a plurality of lower through vias;
bonding the plurality of upper connectors to the plurality of lower connectors;
performing a copper electroplating process to form a plurality of lower backside copper pads over a backside of the lower substrate; and
forming a plurality of conductive bumps over the plurality of lower backside copper pads respectively.

18. The manufacturing method of the semiconductor package as claimed in claim 17, wherein forming the plurality of conductive bumps over the plurality of lower backside copper pads respectively further comprising:
forming an etch stop layer over the backside of the lower substrate to cover the plurality of lower backside conductive pads;
forming a dielectric layer over the backside of the lower substrate to cover the etch stop layer and the plurality of lower backside conductive pads;
forming a plurality of openings over the dielectric layer to reveal upper surfaces of the plurality of lower backside conductive pads respectively; and
forming the plurality of conductive bumps in the plurality of openings.

19. The manufacturing method of the semiconductor package as claimed in claim 17, further comprising:
forming an encapsulating material to laterally encapsulate the upper die.

20. The manufacturing method of the semiconductor package as claimed in claim 17, further comprising:
bonding a supporting substrate to a backside of the upper substrate.
